(19) United States
(12) Patent Application Publication
(10) Pub. No.: US 2025/0192033 A1
(43) Pub. Date: Jun. 12, 2025

(54) SEMICONDUCTOR DEVICE AND METHOD FOR FABRICATING THE SAME

(71) Applicant: UNITED MICROELECTRONICS CORP., Hsin-Chu City (TW)

(72) Inventors: Ching-Hua Yeh, Tainan City (TW); Ping-Chia Shih, Tainan City (TW); Che-Hao Kuo, Tainan City (TW); Chia-Min Hung, Tainan City (TW); Po-Hsien Chen, Tainan City (TW); Wan-Chun Liao, Hsinchu County (TW)

(73) Assignee: UNITED MICROELECTRONICS CORP., Hsin-Chu City (TW)

(21) Appl. No.: 18/415,662

(22) Filed: Jan. 18, 2024

(30) Foreign Application Priority Data
Dec. 11, 2023 (CN) 202311694278.9

(51) Int. Cl. H01L 23/525

(52) U.S. Cl. CPC H01L 23/5256

(57) ABSTRACT

A semiconductor device includes an insulating structure, a first electrical fuse element, a second electrical fuse element, a first spacer, a second spacer and an epitaxial structure. The insulating structure is disposed in a substrate. The first electrical fuse element and the second electrical fuse element are disposed at two sides of the insulating structure. Each of the first electrical fuse element and the second electrical fuse element includes a semiconductor layer disposed on the substrate and a mask layer disposed on the semiconductor layer. The first spacer partially covers a sidewall of the semiconductor layer of the first electrical fuse element adjacent to the insulating structure. The second spacer partially covers a sidewall of the semiconductor layer of the second electrical fuse element adjacent to the insulating structure. The epitaxial structure is disposed above the insulating structure and electrically connects the two semiconductor layers.

### BACKGROUND OF THE INVENTION

### 1. Field of the Invention

The present disclosure relates to the field of semiconductor devices, and more particularly, to a semiconductor device including electrical fuse elements and a method for fabricating the same.

### 2. Description of the Prior Art

With the miniaturization and the increased complexity of semiconductor processes, semiconductor devices become more susceptible to various defects. Therefore, in addition forming elements, such as metal connections, diodes or transistors, some fusible links, i.e., fuses or electrical fuses (e-fuses), are also formed in the integrated circuit to ensure the utilizability of the integrated circuit.

In general, fuses/electrical fuses are configured for being electrically connected with the redundancy circuit in the integrated circuit. Once defects are detected in the circuit, the fuses/electrical fuses may be used to repair or replace the portion of the circuit with the defects. Moreover, current electrical fuses may be designed to provide programmable functions. For example, redundant information, batch numbers, or security codes may be stored in the electrical fuses to unique each chip.

In addition, with the rise of Internet of Things (IoT), more and more data are stored and shared digitally, and the security of the architecture is increasingly valued. In the past, information security of Internet of Things mainly focused on software and encrypted network connections. However, in addition to the security of network, the security of physical equipment also be threatened. Once counterfeit chips or other problem emerges, hackers may remotely control the equipment, acquire key or other sensitive information through internet, and in turn cause a loss for company.

Therefore, hardware security technology begins to receive increasing attention. For example, physically unclonable function (PUF) is a type of hardware security technology. Its principle is to introduce various random variables in the semiconductor processes to produce slight differences in the microstructures of the manufactured chips. Due to the unpredictable and uncontrollable nature of random variables, it is almost impossible to replicate the chip. The properties of randomness, uniqueness and non-replicability make PUF a kind of chip fingerprint, which can greatly improve the information security of Internet of Things. Therefore, how to introduce random variables into the semiconductor processes to realize the PUF function has become one of the development focuses of relevant industries.

### SUMMARY OF THE INVENTION

According to one aspect of the present disclosure, a semiconductor device includes an insulating structure, a first electrical fuse element, a second electrical fuse element, a first spacer, a second spacer and an epitaxial structure. The insulating structure is disposed in a substrate. The first electrical fuse element and the second electrical fuse element are disposed at two sides of the insulating structure. Each of the first electrical fuse element and the second electrical fuse element includes a semiconductor layer disposed on the substrate and a mask layer disposed on the semiconductor layer. The first spacer partially covers a sidewall of the semiconductor layer of the first electrical fuse element adjacent to the insulating structure. The second spacer partially covers a sidewall of the semiconductor layer of the second electrical fuse element adjacent to the insulating structure. The epitaxial structure is disposed above the insulating structure and electrically connects the semiconductor layer of the first electrical fuse element to the semiconductor layer of the second electrical fuse element.

According to another aspect of the present disclosure, a method for fabricating a semiconductor device is disclosed. The method includes steps as follows. An insulating structure is formed in a substrate. A first electrical fuse element and a second electrical fuse element are formed at two sides of the insulating structure, in which each of the first electrical fuse element and the second electrical fuse element includes a semiconductor layer disposed on the substrate and a mask layer disposed on the semiconductor layer. A first spacer is formed to partially cover a sidewall of the semiconductor layer of the first electrical fuse element adjacent to the insulating structure. A second spacer is formed to partially cover a sidewall of the semiconductor layer of the second electrical fuse element adjacent to the insulating structure. An epitaxial structure is formed above the insulating structure and electrically connecting the semiconductor layer of the first electrical fuse element to the semiconductor layer of the second electrical fuse element is formed.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1, FIG. 2, FIG. 3, FIG. 4, FIG. 5, FIG. 6, FIG. 7 and FIG. 8 are schematic cross-sectional views showing steps of a method for fabricating a semiconductor device according to an embodiment of the present disclosure.

FIG. 9 is a schematic cross-sectional view showing a step of a method for fabricating a semiconductor device according to another embodiment of the present disclosure.

FIG. 10 is a schematic top view of a semiconductor device according to an embodiment of the present disclosure.

### DETAILED DESCRIPTION

In the following detailed description of the embodiments, reference is made to the accompanying drawings which form a part thereof, and in which is shown by way of illustration specific embodiments in which the disclosure may be practiced. In this regard, directional terminology, such as up, down, left, right, front, back, bottom or top is used with reference to the orientation of the Figure(s) being described. The elements of the present disclosure can be positioned in a number of different orientations. As such, the directional terminology is used for purposes of illustration and is in no way limiting. In addition, identical numeral references or similar numeral references are used for identical elements or similar elements in the following embodiments.

Hereinafter, for the description of “the first feature is formed on or above the second feature”, it may refer that “the first feature is in contact with the second feature directly”, or it may refer that “there is another feature between the first feature and the second feature”, such that the first feature is not in contact with the second feature directly.

It is understood that, although the terms first, second, etc. may be used herein to describe various elements, regions, layers and/or sections, these elements, regions, layers and/or sections should not be limited by these terms. These terms may be only used to distinguish one element, region, layer and/or section from another element, region, layer and/or section. Terms such as “first,” “second,” and other numerical terms when used herein do not imply a sequence or order unless clearly indicated by the context. Thus, a first element, region, layer and/or section discussed below could be termed a second element, region, layer and/or section without departing from the teachings of the embodiments. The terms used in the claims may not be identical with the terms used in the specification, but may be used according to the order of the elements claimed in the claims.

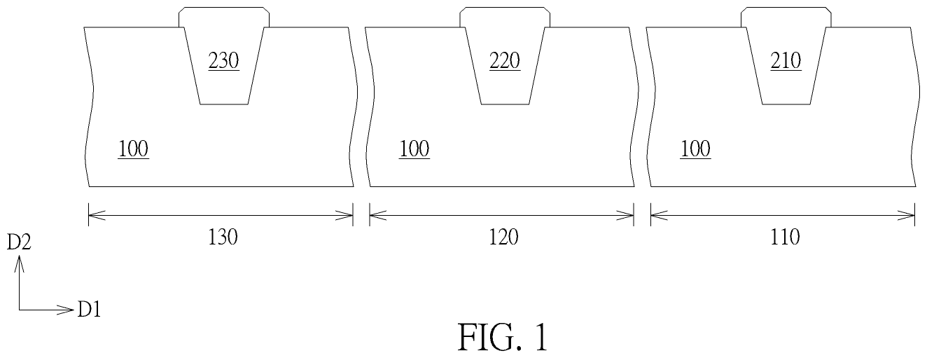

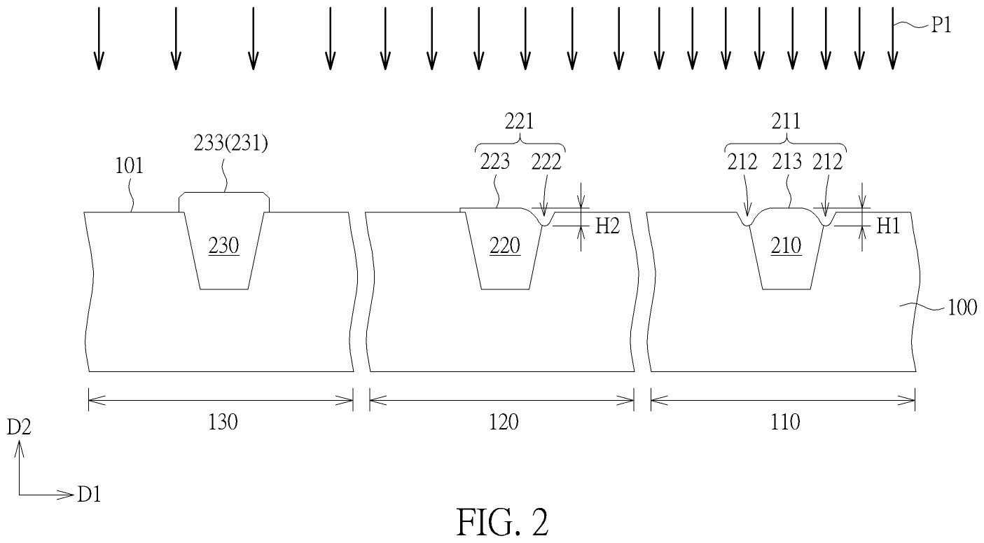

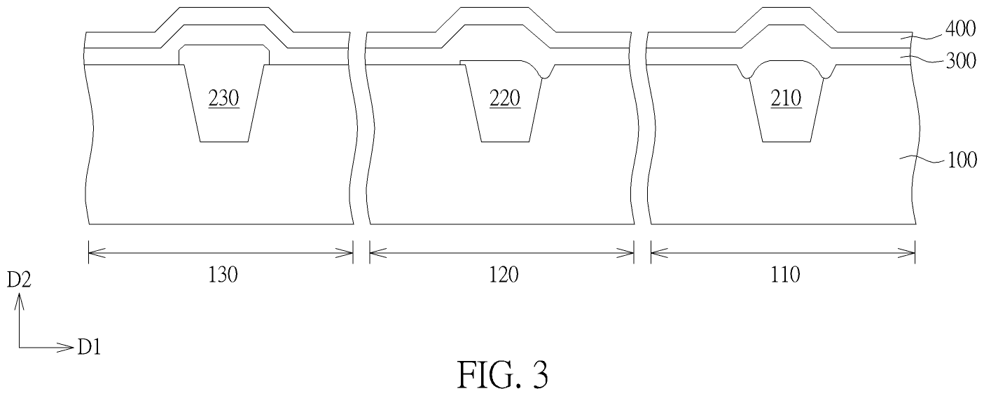

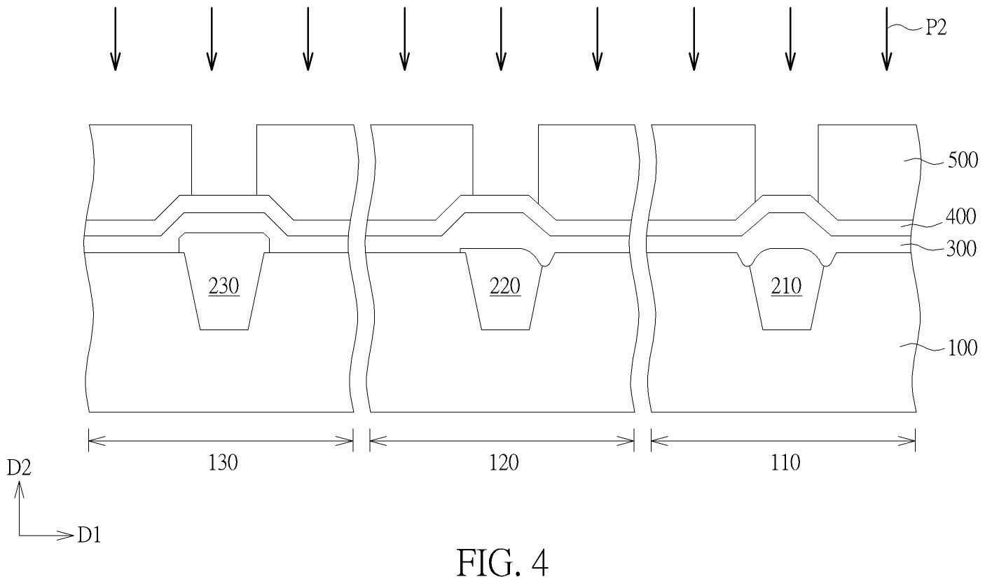

Please refer to FIG. 1 to FIG. 8, which are schematic cross-sectional views showing steps of a method for fabricating a semiconductor device according to an embodiment of the present disclosure. In FIG. 1, a substrate 100 is provided first. The substrate 100 may be a silicon substrate, an epitaxial silicon substrate, a silicon carbide substrate or a silicon on insulator (SOI) substrate. The substrate 100 includes a first element region 110, a second element region 120 and a third element region 130. Next, an insulating structure is formed in the substrate 100. Herein, three insulating structures are exemplarily formed, which are the first insulating structure 210, the second insulating structure 220 and the third insulating structure 230. The first insulating structure 210 is located in the first element region 110, the second insulating structure 220 is located in the second element region 120, and the third insulating structure 230 is located in the third element region 130. The first insulating structure 210, the second insulating structure 220 and the third insulating structure 230 may be, for example, shallow trench isolations (STIs), and the material of the first insulating structure 210, the second insulating structure 220 and the third insulating structure 230 may be, for example, silicon dioxide. It should be noted that the first element region 110, the second element region 120, and the third element region 130 are adjacent to each other in FIG. 1, which is for the convenience of drawing and explanation, and is not for limiting the present disclosure.

Next, as shown in FIG. 2, an ion implantation process P1 is performed, in which the energies and/or doses of the ion implantation process P1 in the first element region 110 and the second element region 120 are higher than that in the third element region 130, so that the heights (not labeled) of the first insulating structure 210 and the second insulating structure 220 protruding from the top surface 101 of the substrate 100 are lower than the height (not labeled) of the third insulating structure 230 protruding from the top surface 101 of the substrate 100, and the top surface 211 of the first insulating structure 210 and the top surface 221 of the second insulating structure 220 are easier to form recessed portions 212 and 222 than the top surface 231 of the third insulating structure 230. Herein, two recessed portions 212 are formed at two sides of the top surface 211 of the first insulating structure 210 and a recessed portion 222 is formed at one side of the top surface 221 of the second insulating structure 220 through the ion implantation process P1. However, it is only exemplary, and the present disclosure is not limited thereto. For example, in other embodiments, two recessed portions 212 may be respectively formed at two sides of the top surface 211 of the first insulating structure 210, and two recessed portions 222 may be respectively formed at two sides of the top surface 221 of the second insulating structure 220. Alternatively, only one recessed portion 212 is formed at one side of the top surface 211 of the first insulating structure 210, and two recessed portions 222 are respectively formed at two sides of the top surface 221 of the second insulating structure 220. In other words, the present disclosure may utilize the process variation generated by the ion implantation process P1 to randomly form the recessed portions (such as the recessed portions 212 and 222) on the insulating structures (such as the first insulating structure 210 and the second insulating structure 220) in the element regions (such as the first element region 110 and the second element region 120) in which the energies and/or doses of the ion implantation process P1 are higher. The aforementioned “recessed portion” (such as the recessed portions 212 and 222) may refer to the portion at the top end of the insulating structure (such as the first insulating structure 210 and the second insulating structure 220) which is recessed and lower than the top surface 101 of the substrate 100.

In FIG. 2, the top surface 211 of the first insulating structure 210 includes a flat portion 213 and two recessed portions 212. The flat portion 213 is connected between the two recessed portions 212. The height difference H1 between the flat portion 213 and one of the recessed portions 212 in the vertical direction D2 may range from 100 angstroms to 140 angstroms. The aforementioned height difference H1 may be defined as the depth of one of the recessed portions 212. The aforementioned vertical direction D2 may be, for example, parallel to the normal direction of the top surface 101 of the substrate 100. In FIG. 2, the height differences H1 between the two recessed portions 212 and the flat portion 213 of the first insulating structure 210 in the vertical direction D2 are the same. However, it is only exemplary. Due to the process variation, the height differences H1 between the two recessed portions 212 and the flat portion 213 of the first insulating structure 210 in the vertical direction D2 may be slightly different.

The top surface 221 of the second insulating structure 220 includes a flat portion 223 and a recessed portion 222. The flat portion 223 is connected with the recessed portion 222. The height difference H2 between the flat portion 223 and the recessed portion 222 in the vertical direction D2 may range from 100 angstroms to 140 angstroms. In FIG. 2, the height difference H2 is the same as the height difference H1. However, it is only exemplary. Due to the process variation, the height difference H2 and the height difference H1 may be slightly different. The top surface 231 of the third insulating structure 230 only includes the flat portion 233 and does not include a recessed portion.

Specifically, although the energies and/or doses of the ion implantation process P1 in the first element region 110 and the second element region 120 are the same, due to the process variation, the number and/or the depths of the recessed portions 212 formed on the top surface 211 of the first insulating structure 210 may be different from the number and/or the depths of the recessed portions 222 formed on the top surface 221 of the second insulating structure 220. In addition, since the energy and/or dose of the ion implantation process P1 in the third element region 130 are lower, the top surface 231 of the third insulating structure 230 is not formed with a recessed portion.

In some embodiments, the ion implantation process P1 may be performed together with the ion implantation process that forms a well region (not shown) or source/drain regions (not shown) in the substrate 100 when fabricating a transistor. For example, the semiconductor device may further include a transistor (not shown). Therefore, the process of forming the recessed portions 212 and 222 may be integrated into the process of fabricating the transistor to simplify the process, but not limited thereto. In some embodiments, a Boolean operation may be used to control the energies and/or doses of the ion implantation process P1 in the first element region 110 and the second element region 120 to be different from the energy and/or dose of the ion implantation process P1 in the third element region 130. How to control the energies and/or doses of the ion implantation process P1 in different element regions is well known in the art and is omitted herein.

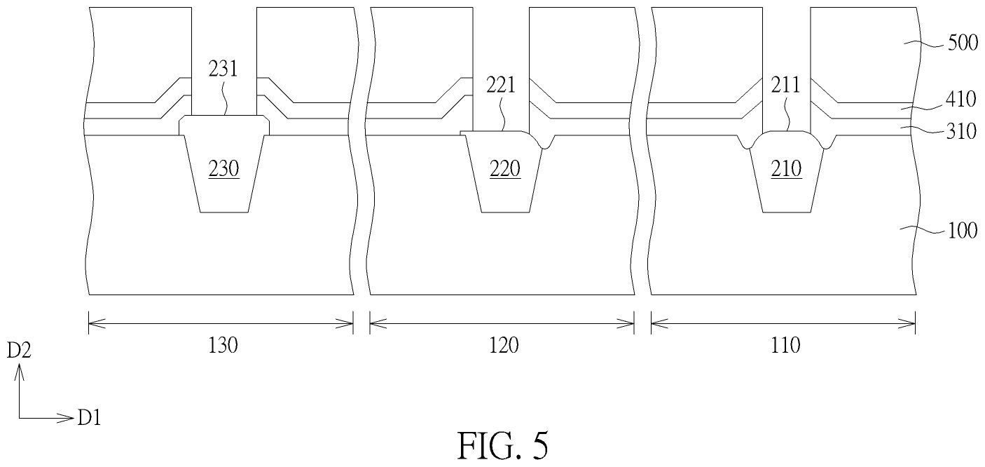

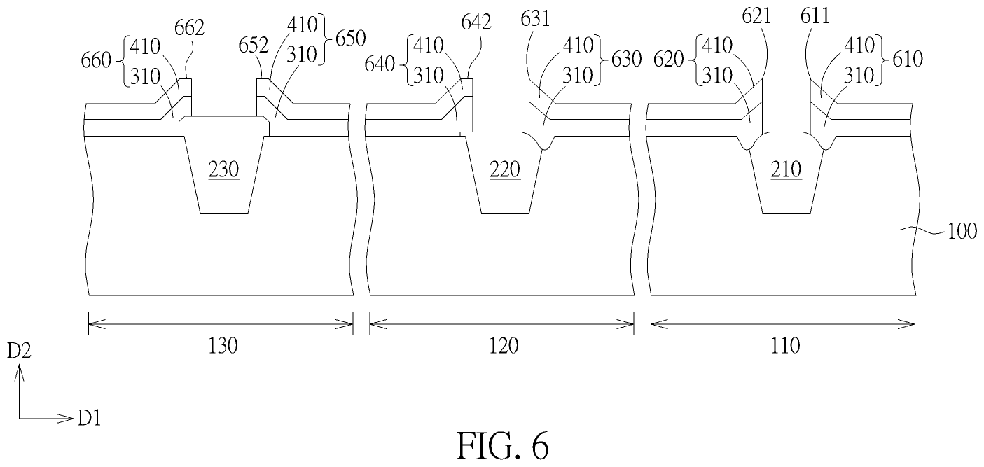

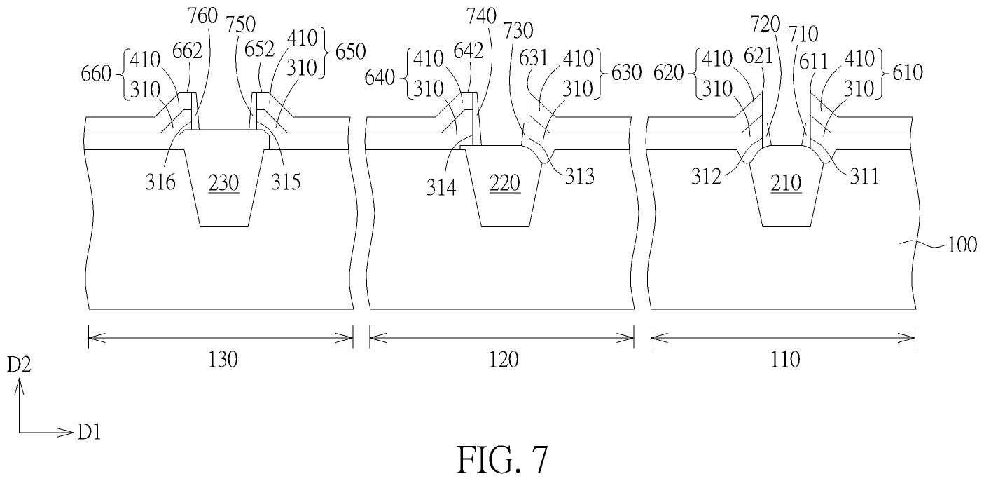

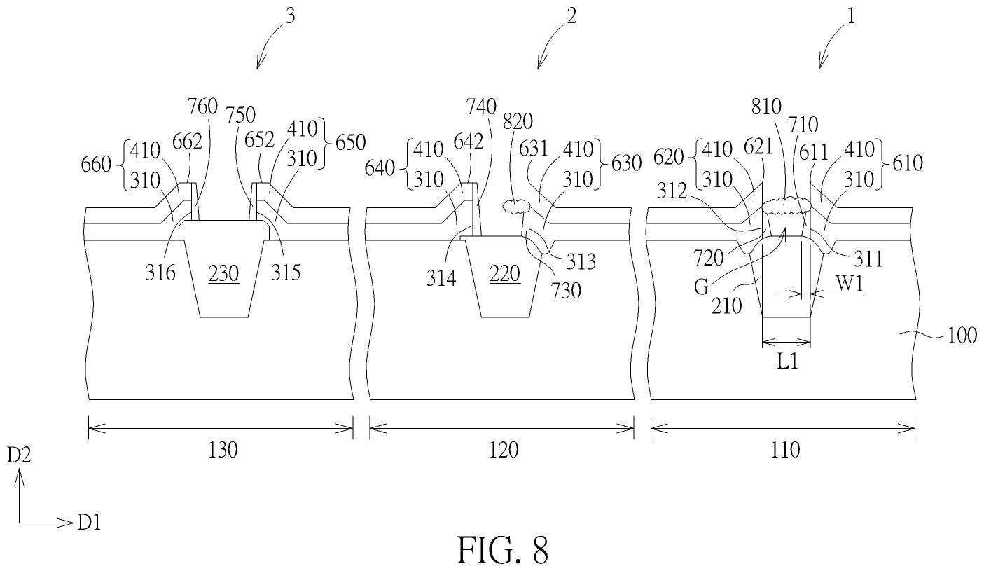

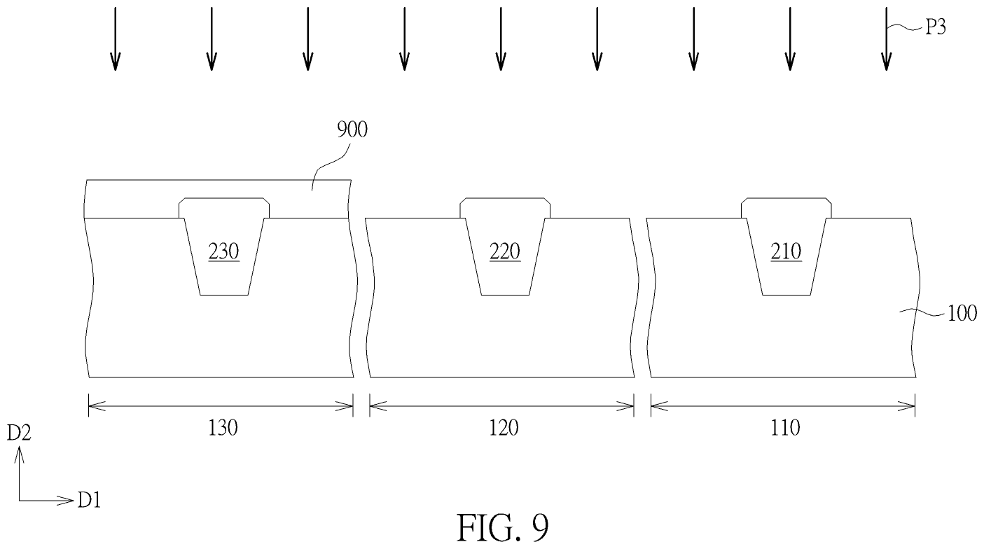

In FIG. 2, the recessed portions 212 and 222 are formed by the ion implantation process P1. However, the present disclosure is not limited thereto. For example, please refer to FIG. 9, which is a schematic cross-sectional view showing a step of a method for fabricating a semiconductor device according to another embodiment of the present disclosure, which is performed after the step shown in FIG. 1. In FIG. 9, a mask layer 900 is firstly formed to cover the third element region 130, and then a portion of the first insulating structure 210 and a portion of the second insulating structure 220 are removed through an etching process P3, so that the height (not labeled) of the first insulating structure 210 and the height (not labeled) of the second insulating structure 220 protruding from the top surface 101 (see FIG. 2) of the substrate 100 are lower than the height (not labeled) of the third insulating structure 230 protruding from the top surface 101 of the substrate 100, and the recessed portions 212 and 222 are respectively formed on the top surface 211 of the first insulating structure 210 and the top surface 221 of the second insulating structure 220, and then the mask layer 900 is removed. After the etching process P3 is performed, the structures of the first insulating structure 210, the second insulating structure 220 and the third insulating structure 230 may refer to the structures shown in FIG. 2 and related description. The aforementioned etching process P3 may be a wet etching process. For example, buffered oxide etch (BOE) may be used to etch the first insulating structure 210 and the second insulating structure 220, but not limited thereto. In other words, the present disclosure may also utilize the process variation generated by the etching process P3 to randomly form the recessed portions (such as the recessed portions 212 and 222) on the insulating structures (such as the first insulating structure 210 and the second insulating structure 220) in the element regions (such as the first element region 110 and the second element region 120) which are performed with the etching process P3.

Next, as shown in FIG. 3, a semiconductor material layer 300 is formed on the substrate 100, and a mask material layer 400 is formed on the semiconductor material layer 300. Next, the semiconductor material layer 300 and the mask material layer 400 are patterned. For example, as shown in FIG. 4, the patterned mask 500 may be formed on the mask material layer 400, and then the etching process P2 is performed to remove the portions of the semiconductor material layer 300 and the mask material layer 400 not covered by the patterned mask 500 to expose the top surface 211 of the first insulating structure 210, the top surface 221 of the second insulating structure 220, and the top surface 231 of the third insulating structure 230, as shown in FIG. 5.

Next, as shown in FIG. 6, the patterned mask 500 is removed to obtain a first electrical fuse element 610 and a second electrical fuse element 620 at two sides of the first insulating structure 210, a third electrical fuse element 630 and a fourth electrical fuse element 640 at two sides of the second insulating structure 220, and a fifth electrical fuse element 650 and a sixth electrical fuse element 660 at two sides of the third insulating structure 230. Each of the first electrical fuse element 610, the second electrical fuse element 620, the third electrical fuse element 630, the fourth electrical fuse element 640, the fifth electrical fuse element 650 and the sixth electrical fuse element 660 includes a semiconductor layer 310 and a mask layer 410, the semiconductor layer 310 is disposed on the substrate 100, and the mask layer 410 is disposed on the semiconductor layer 310. The material of the semiconductor layer 310 may include, for example, polycrystalline silicon or amorphous silicon. The material of the mask layer 410 may include, for example, silicon dioxide (SiO₂), silicon nitride (SiN), silicon carbide (SiC) and/or silicon oxynitride (SiON).

Because the first insulating structure 210 is formed with the recessed portions 212, the first electrical fuse element 610 includes a sharp corner structure 611 at a side adjacent to the first insulating structure 210, and the second electrical fuse element 620 includes a sharp corner structure 621 at a side adjacent to the first insulating structure 210. Because the second insulating structure 220 is formed with the recessed portion 222, the third electrical fuse element 630 includes a sharp corner structure 631 at a side adjacent to the second insulating structure 220. Corresponding to the flat portion 223 (see FIG. 2) of the second insulating structure 220, the fourth electrical fuse element 640 has a flat structure 642 at a side adjacent to the second insulating structure 220. Corresponding to the flat portion 233 (see FIG. 2) of the third insulating structure 230, the fifth electrical fuse element 650 has a flat structure 652 at a side adjacent to the third insulating structure 230, and the sixth electrical fuse element 660 has a flat structure 662 at a side adjacent to the third insulating structure 230.

Next, as shown in FIG. 7, the first spacer 710 is formed to partially cover the sidewall 311 of the semiconductor layer 310 of the first electrical fuse element 610 adjacent to the first insulating structure 210. The second spacer 720 is formed to partially cover the sidewall 312 of the semiconductor layer 310 of the second electrical fuse element 620 adjacent to the first insulating structure 210. The third spacer 730 is formed to partially cover the sidewall 313 of the semiconductor layer 310 of the third electrical fuse element 630 adjacent to the second insulating structure 220. The fourth spacer 740 is formed to completely cover the sidewall 314 of the semiconductor layer 310 of the fourth electrical fuse element 640 adjacent to the second insulating structure 220. The fifth spacer 750 is formed to completely cover the sidewall 315 of the semiconductor layer 310 of the fifth electrical fuse element 650 adjacent to the third insulating structure 230. The sixth spacer 760 is formed to completely cover the sidewall 316 of the semiconductor layer 310 of the sixth electrical fuse element 660 adjacent to the third insulating structure 230. The width W1 (see FIG. 8) of the first spacer 710 in the horizontal direction D1 may decrease from bottom to top. The aforementioned horizontal direction D1 may be, for example, perpendicular to the normal direction of the top surface 101 of the substrate 100. Similarly, the width (not labeled) of any of the second spacer 720 to the sixth spacer 760 in the horizontal direction D1 may also decrease from bottom to top.

Specifically, the first spacer 710 to the sixth spacer 760 may be formed simultaneously, and may include steps as follows. A spacer material layer (not shown) is deposited to completely cover the top surfaces (not labeled) and the sidewalls (not labeled) of the first electrical fuse element 610 to the sixth electrical fuse element 660, the top surface 211 of the first insulating structure 210, the top surface 221 of the second insulating structure 220, and the top surface 231 of the third insulating structure 230. Next, one or more etching processes and/or cleaning processes are performed to completely remove the portions of the spacer material layer on the top surfaces of the first electrical fuse element 610 to the sixth electrical fuse element 660, the top surface 211 of the first insulating structure 210, the top surface 221 of the second insulating structure 220 and the top surface 231 of the third insulating structure 230. During the process, the portions of the spacer material layer on the sidewalls of the first electrical fuse element 610 to the sixth electrical fuse element 660 are also be partially removed, and the remaining portions of the spacer material layer form the first spacer 710 to the sixth spacer 760. Due to the sharp corner structures 611, 621 and 631, it is unfavorable for the first spacer 710, the second spacer 720 and the third spacer 730 to completely cover the sidewalls of the first electrical fuse element 610, the second electrical fuse element 620 and the third electrical fuse element 630, so that the first spacer 710, the second spacer 720 and the third spacer 730 partially cover the sidewall 311 of the semiconductor layer 310 of the first electrical fuse element 610, the sidewall 312 of the semiconductor layer 310 of the second electrical fuse element 620 and the sidewall 313 of the semiconductor layer 310 of the third electrical fuse element 630, respectively. More specifically, the heights of the semiconductor layers 310 above the recessed portions 212 and 222 in the vertical direction D2 may be greater than the heights of the semiconductor layers 310 above the flat portions 223 and 233 in the vertical direction D2, which is unfavorable for the first spacer 710, the second spacer 720 and the third spacer 730 to completely cover the sidewalls of the first electrical fuse element 610, the second electrical fuse element 620 and the third electrical fuse element 630. The materials of the first spacer 710 to the sixth spacer 760 may include oxides and/or nitrides, such as silicon dioxide, silicon nitride, silicon oxynitride or silicon carbonitride.

Next, as shown in FIG. 8, an epitaxial growth process is performed to form an epitaxial structure 810 above the first insulating structure 210 and electrically connecting the semiconductor layer 310 of the first electrical fuse element 610 to the semiconductor layer 310 of the second electrical fuse element 620, and to form an epitaxial structure 820 above the second insulating structure 220 and connected with the semiconductor layer 310 of the third electrical fuse element 630.

Specifically, because the sidewall 311 of the semiconductor layer 310 of the first electrical fuse element 610, the sidewall 312 of the semiconductor layer 310 of the second electrical fuse element 620, and the sidewall 313 of the semiconductor layer 310 of the third electrical fuse element 630 are only partially covered by the first spacer 710, the second spacer 720 and the third spacer 730, respectively, the epitaxy is grown from the uncovered portions of the sidewalls 311, 312 and 313 during the epitaxial growth process. The epitaxy grown from the sidewall 311 and the epitaxy grown from the sidewall 312 are connected to form the epitaxial structure 810. The epitaxial structure 810 allows the semiconductor layer 310 of the first electrical fuse element 610 and the semiconductor layer 310 of the second electrical fuse element 620 to electrically connected with each other, so that a conductive path is formed between the first electrical fuse element 610 and the second electrical fuse element 620. Because the sidewall 314 is completely covered by the fourth spacer 740, the epitaxial structure 820 grown from the sidewall 313 cannot electrically connect the semiconductor layer 310 of the third electrical fuse element 630 to the semiconductor layer 310 of the fourth electrical fuse element 640. Therefore, there is no conductive path formed between the third electrical fuse element 630 and the fourth electrical fuse element 640. There is no epitaxial structure formed between the fifth electrical fuse element 650 and the sixth electrical fuse element 660. Accordingly, there is no conductive path formed between the fifth electrical fuse element 650 and the sixth electrical fuse element 660.

In FIG. 8, a gap G is between the epitaxial structure 810 and the first insulating structure 210 in the vertical direction D2. The material of the epitaxial structure 810 may include silicon germanium (SiGe). The length L1 of the epitaxial structure 810 in the horizontal direction D1 may range from 530 angstroms to 570 angstroms. The length L1 is substantially the same as the distance between the sidewall 311 and the sidewall 312 in the horizontal direction D1. Thereby, it is beneficial for the epitaxy grown from the sidewall 311 and the epitaxy grown from the sidewall 312 to connect to form the epitaxial structure 810.

In some embodiment according to the present disclosure, the first spacer 710 to the sixth spacer 760 may be formed together with the spacer surrounding a gate structure (not shown) and defining lightly doped drain (LDD) regions (not shown) and/or defining source/drain regions (not shown) when fabricating a transistor. The epitaxial structures 810 and 820 may also be formed together with epitaxial structures (not shown) formed at two sides of a gate structure and in the substrate 100 for increasing the channel stress when fabricating a transistor. For example, the semiconductor device may further include a transistor (not shown). Therefore, the process of forming the first spacer 710 to the sixth spacer 760 and the epitaxial structures 810 and 820 may be integrated into the process of fabricating the transistor to simplify the process, but not limited thereto.

The aforementioned film layers, such as the semiconductor material layer 300, the mask material layer 400, the patterned mask 500, the mask layer 900, the first spacer 710 to the sixth spacer 760, may be formed by any suitable methods. For example, the methods may be, but are not limited to, molecular-beam epitaxy (MBE), chemical vapor deposition (CVD), metal organic chemical vapor deposition (MOCVD), hydride vapor phase epitaxy (HVPE) and atomic layer deposition (ALD).

Please refer to FIG. 8, which is a schematic top view of a semiconductor device according to an embodiment of the present disclosure. As shown in the first element region 110, the semiconductor device may include the first element 1. The first element 1 includes the first insulating structure 210, the first electrical fuse element 610, the second electrical fuse element 620, the first spacer 710, the second spacer 720, and the epitaxial structure 810. The first insulating structure 210 is disposed in the substrate 100. The first electrical fuse element 610 and the second electrical fuse element 620 are disposed at two sides of the first insulating structure 210, respectively. Each of the first electrical fuse element 610 and the second electrical fuse element 620 includes the semiconductor layer 310 and the mask layer 410. The semiconductor layer 310 is disposed on the substrate 100, and the mask layer 410 is disposed on the semiconductor layer 310. The first spacer 710 partially covers the sidewall 311 of the semiconductor layer 310 of the first electrical fuse element 610 adjacent to the first insulating structure 210. The second spacer 720 partially covers the sidewall 312 of the semiconductor layer 310 of the second electrical fuse element 620 adjacent to the first insulating structure 210. The epitaxial structure 810 is disposed above the first insulating structure 210 and electrically connects the semiconductor layer 310 of the first electrical fuse element 610 to the semiconductor layer 310 of the second electrical fuse element 620. The first element 1 further includes a gap G between the epitaxial structure 810 and the first insulating structure 210 in the vertical direction D2. For other details of the first element 1, references may be made to the above description and are not repeated herein.

As shown in the second element region 120, the semiconductor element may further include the second element 2. The second element 2 includes the second insulating structure 220, the third electrical fuse element 630, the fourth electrical fuse element 640, the third spacer 730, the fourth spacer 740 and the epitaxial structure 820. The second insulating structure 220 is disposed in the substrate 100. The third electrical fuse element 630 and the fourth electrical fuse element 640 are disposed at two sides of the second insulating structure 220, respectively. Each of the third electrical fuse element 630 and the fourth electrical fuse element 640 includes the semiconductor layer 310 and the mask layer 410. The semiconductor layer 310 is disposed on the substrate 100, and the mask layer 410 is disposed on the semiconductor layer 310. The third spacer 730 partially covers the sidewall 313 of the semiconductor layer 310 of the third electrical fuse element 630 adjacent to the second insulating structure 220. The fourth spacer 740 completely covers the sidewall 314 of the semiconductor layer 310 of the fourth electrical fuse element 640 adjacent to the second insulating structure 220. The epitaxial structure 820 is disposed above the second insulating structure 220 and connected with the semiconductor layer 310 of the third electrical fuse element 630. The main difference between the second element 2 and the first element 1 is that the epitaxial structure 820 cannot electrically connect the semiconductor layer 310 of the third electrical fuse element 630 to the semiconductor layer 310 of the fourth electrical fuse element 640 which are adjacent to each other due to the semiconductor layer 310 of the fourth electrical fuse element 640 being completely covered by the fourth spacer 740. For other details of the second element 2, reference may be made to the above description and are not repeated herein.

As shown in the third element region 130, the semiconductor device may further include the third element 3. The third element 3 includes the third insulating structure 230, the fifth electrical fuse element 650, the sixth electrical fuse element 660, the fifth spacer 750 and the sixth spacer 760. The third insulating structure 230 is disposed in the substrate 100. The fifth electrical fuse element 650 and the sixth electrical fuse element 660 are disposed at two sides of the third insulating structure 230, respectively. Each of the fifth electrical fuse element 650 and the sixth electrical fuse element 660 includes the semiconductor layer 310 and the mask layer 410, the semiconductor layer 310 is disposed on the substrate 100, and the mask layer 410 is disposed on the semiconductor layer 310. The fifth spacer 750 completely covers the sidewall 315 of the semiconductor layer 310 of the fifth electrical fuse element 650 adjacent to the third insulating structure 230. The sixth spacer 760 completely covers the sidewall 316 of the semiconductor layer 310 of the sixth electrical fuse element 660 adjacent to the third insulating structure 230. The main difference between the third element 3 and the first element 1 is that the semiconductor layer 310 of the fifth electrical fuse element 650 and the semiconductor layer 310 of the sixth electrical fuse element 660 are completely covered by the fifth spacer 750 and the sixth spacer 760, respectively. Accordingly, the third element 3 does not have an epitaxial structure to electrically connect the semiconductor layer 310 of the fifth electrical fuse element 650 to the semiconductor layer 310 of the sixth electrical fuse element 660 which are adjacent to each other. For other details of the third element 3, reference may be made to the above description and are not repeated herein.

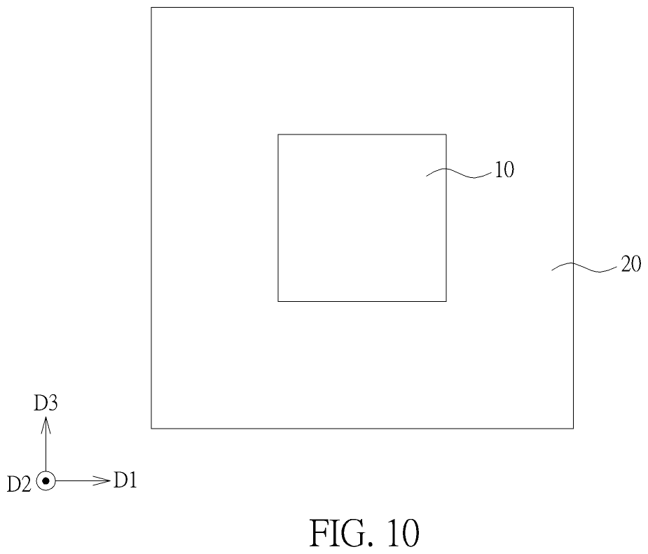

Please refer to FIG. 10, which is a schematic top view of a semiconductor device according to an embodiment of the present disclosure. The semiconductor device includes a region 10 and region 20. For example, the region 10 may be configured as a PUF unit, and the region 20 may be disposed with elements that implement the main functions of the semiconductor device, such as transistors (not shown), diodes (not shown), metal connections (not shown) and electrical fuse elements (such as the fifth electrical fuse element 650 and the sixth electrical fuse element 660 in the third element region 130).

The aforementioned first element region 110 and second element region 120 may be disposed in the region 10, and the third element region 130 may be disposed in the region 20. The fifth electrical fuse element 650 and the sixth electrical fuse element 660 in the third element region 130 may be configured for repairing or replacing the portion of circuit which is detected with defects, so as to ensure the utilizability of the semiconductor device.

For example, the region 10 may include an electrical fuse element matrix formed by a plurality of electrical fuse elements (such as the first electrical fuse element 610, the second electrical fuse element 620, the third electrical fuse element 630 and the fourth electrical fuse element 640) arranged along the horizontal direction D1 and the horizontal direction D3. Herein, the horizontal direction D3 is perpendicular to the horizontal direction D1. However, it is only exemplary, and the present disclosure is not limited thereto. Two adjacent electrical fuse elements may be disposed with an insulating structure (such as the first insulating structure 210 and the second insulating structure 220) therebetween. The region 10 may further include a plurality of word lines (not shown) and a plurality of bit lines (not shown) to control the plurality of electrical fuse elements, such as addressing and reading the plurality of electrical fuse elements.

When fabricating the semiconductor device, after forming the plurality of insulating structures in the substrate 100, the ion implantation process P1 as shown in FIG. 2 in which the energy and/or dose thereof in the region 10 are higher than the energy and/or dose thereof in the region 20 may be performed, or the etching process P3 as shown in FIG. 9 may be performed with the mask layer 900 formed on the region 20 to remove a portion of the insulating structures in the region 10, so that the heights of the plurality of insulating structures in the region 10 protruding from the top surface 101 of the substrate 100 are lower than the heights of the plurality of insulating structures in the region 20 protruding from the top surface 101 of the substrate 100, and recessed portions (such as the recessed portions 212 and 222 in FIG. 2) are formed on the top surfaces of the plurality of insulating structures in the region 10. In other words, according to the present disclosure, with performing at least one additional ion implantation process P1 and/or the etching process P3 in the region 10, unexpected recessed portions may be randomly formed on the insulating structures in the region 10, which allows the plurality of electrical fuse elements sequentially formed to have process variation and may realized the PUF function.

Specifically, due to the process variation, the number and depths of the recessed portions formed on the plurality of insulating structures in the region 10 are different. As a result, some of the subsequently formed spacers (such as the first spacer 710, the second spacer 720 and the third spacer 730) partially cover the sidewalls of the semiconductor layers of the electrical fuse elements, and some of the subsequently formed spacers (such as the fourth spacer 740) completely cover the semiconductor layers of the electrical fuse elements, so that some electrical fuse elements are formed with the epitaxial structures therebetween to electrically connect the electrical fuse elements (such as the first element 1 shown in FIG. 8), and some electrical fuse elements cannot be formed with the epitaxial structure therebetween to electrically connecting the electrical fuse elements (such as the second element 2 in FIG. 8). In addition, it can be defined through circuit design that two electrical fuse elements having the epitaxial structure therebetween to electrically connect the two electrical fuse elements represents one of 0 and 1, and two electrical fuse elements having no epitaxial structure therebetween to electrically connect the two electrical fuse elements represents the other one of 0 and 1. That is, the electrical fuse element matrix in the region 10 may correspond to a logic matrix composed of 0 and 1.

Due to the random property of the process variation, the electrical fuse elements with the epitaxial structure to electrically connected therebetween are randomly distributed in the region 10. In other words, 0 and 1 of the logic matrix are also randomly distributed and may be used as the innate electronic fingerprint of the semiconductor device 1. The logic matrix may be used as an encrypted key to identify the chip or device, and may realize the PUF function. How to control the plurality of electrical fuse elements through word lines and bit lines, and how to define different states of the electrical fuse elements to correspond to either 0 or 1 through circuit design are well known in the art and are omitted herein.

Compared with the prior art, in the present disclosure, when fabricating the electrical fuse element, the spacer is allowed to only partially cover the semiconductor layer of the electrical fuse element by utilizing the process variation, it is favorable for forming an epitaxial structure to electrically connect two adjacent electrical fuse elements. When applied to fabricate a matrix of electrical fuse elements, some of the adjacent electrical fuse elements may be randomly formed with the epitaxial structure therebetween to electrically connect the adjacent electrical fuse elements, while some of the adjacent electrical fuse elements have no epitaxial structure therebetween to electrically connect the adjacent electrical fuse elements. Accordingly, the purpose of random encoding can be achieved, so as to realize the PUF function.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
an insulating structure disposed in a substrate;
a first electrical fuse element and a second electrical fuse element disposed at two sides of the insulating structure, wherein each of the first electrical fuse element and the second electrical fuse element comprises a semiconductor layer disposed on the substrate and a mask layer disposed on the semiconductor layer;
a first spacer partially covering a sidewall of the semiconductor layer of the first electrical fuse element adjacent to the insulating structure;
a second spacer partially covering a sidewall of the semiconductor layer of the second electrical fuse element adjacent to the insulating structure; and
an epitaxial structure disposed above the insulating structure and electrically connecting the semiconductor layer of the first electrical fuse element to the semiconductor layer of the second electrical fuse element.

2. The semiconductor device of claim 1, further comprising:
a gap between the epitaxial structure and the insulating structure in a vertical direction.

3. The semiconductor device of claim 1, wherein a top surface of the insulating structure comprises two recessed portions at two sides thereof.

4. The semiconductor device of claim 3, wherein the top surface of the insulating structure further comprises a flat portion connected between the two recessed portions, and a height difference between the flat portion and one of the recessed portions in a vertical direction ranges from 100 angstroms to 140 angstroms.

5. The semiconductor device of claim 1, wherein each of the first electrical fuse element and the second electrical fuse element comprises a sharp corner structure at a side adjacent to the insulating structure.

6. The semiconductor device of claim 1, wherein a width of the first spacer in a horizontal direction decreases gradually from bottom to top.

7. The semiconductor device of claim 1, wherein a length of the epitaxial structure in a horizontal direction ranges from 530 angstroms to 570 angstroms.

8. The semiconductor device of claim 1, wherein a material of the semiconductor layer comprises polycrystalline silicon or amorphous silicon.

9. The semiconductor device of claim 1, wherein a material of the epitaxial structure comprises silicon germanium.

10. A method for fabricating a semiconductor device, comprising:
forming an insulating structure in a substrate;
forming a first electrical fuse element and a second electrical fuse element at two sides of the insulating structure, wherein each of the first electrical fuse element and the second electrical fuse element comprises a semiconductor layer disposed on the substrate and a mask layer disposed on the semiconductor layer;
forming a first spacer partially covering a sidewall of the semiconductor layer of the first electrical fuse element adjacent to the insulating structure;
forming a second spacer partially covering a sidewall of the semiconductor layer of the second electrical fuse element adjacent to the insulating structure; and
forming an epitaxial structure above the insulating structure and electrically connecting the semiconductor layer of the first electrical fuse element to the semiconductor layer of the second electrical fuse element.

11. The method of claim 10, wherein a gap is between the epitaxial structure and the insulating structure in a vertical direction.

12. The method of claim 10, wherein forming the first electrical fuse element and the second electrical fuse element at the two sides of the insulating structure comprises:
forming a semiconductor material layer on the substrate;
forming a mask material layer on the semiconductor material layer; and
patterning the semiconductor material layer and the mask material layer.

13. The method of claim 10, further comprising:
forming two recessed portions at two sides of a top surface of the insulating structure.

14. The method of claim 13, wherein the top surface of the insulating structure further comprises a flat portion connected between the two recessed portions, and a height difference between the flat portion and one of the recessed portions in a vertical direction ranges from 100 angstroms to 140 angstroms.

15. The method of claim 13, wherein the two recessed portions are formed by an etching process or an ion implantation process.

16. The method of claim 10, wherein each of the first electrical fuse element and the second electrical fuse element comprises a sharp corner structure at a side adjacent to the insulating structure.

17. The method of claim 10, wherein a width of the first spacer in a horizontal direction decreases gradually from bottom to top.

18. The method of claim 10, wherein a length of the epitaxial structure in a horizontal direction ranges from 530 angstroms to 570 angstroms.

19. The method of claim 10, wherein a material of the semiconductor layer comprises polycrystalline silicon or amorphous silicon.

20. The method of claim 10, wherein a material of the epitaxial structure comprises silicon germanium.
